(19) United States
(12) Patent Application Publication
(10) Pub. No.: US 2018/0240749 A1
(43) Pub. Date: Aug. 23, 2018

(54) SEMICONDUCTOR DEVICE AND MANUFACTURING METHOD THEREOF

(71) Applicant: Renesas Electronics Corporation, Tokyo (JP)

(72) Inventor: Kenichiro ABE, Tokyo (JP)

(73) Assignee: Renesas Electronics Corporation, Tokyo (JP)

(21) Appl. No.: 15/900,878

(22) Filed: Feb. 21, 2018

(30) Foreign Application Priority Data
Feb. 22, 2017 (JP) 2017-030914

(51) Int. Cl. H01L 23/528; H01L 29/06; H01L 23/522; H01L 23/532; H01L 21/768

(52) U.S. Cl. CPC H01L 23/528; H01L 29/0649; H01L 23/5226; H01L 21/7682; H01L 23/5228; H01L 21/76895; H01L 23/53261

(57) ABSTRACT

The present invention provides a semiconductor device that reduces the variation of the resistance value of the conductive film. A semiconductor device according to an embodiment includes a semiconductor substrate, a wiring layer, a dielectric film, a metal film, and an interlayer dielectric film. The semiconductor substrate has a first surface. The wiring layer is placed over the first surface. The wiring layer has a first part as well as a second part provided apart from the first part. The dielectric film is placed over the first part. The metal film is placed over the dielectric film. The interlayer dielectric film covers the dielectric film and the metal film, and is located between the first part and the second part. An air gap is provided within the interlayer dielectric film located between the first part and the second part. The air gap extends in a direction crossing the first surface.

### CROSS-REFERENCE TO RELATED APPLICATIONS

The disclosure of Japanese Patent Application No. 2017-030914 filed on Feb. 22, 2017 including the specification, drawings and abstract is incorporated herein by reference in its entirety.

### BACKGROUND

The present invention relates to a semiconductor device and a manufacturing method thereof.

There has been known a semiconductor device including a resistance element. The conventional semiconductor device including a resistance element has a semiconductor substrate, a wiring layer, a dielectric film, a conductive film configuring the resistance element, and an interlayer dielectric film.

The semiconductor substrate has a first surface. The wiring layer is placed over the first surface. The dielectric film is placed over the wiring layer. The conductive film is placed over the dielectric film. For the conductive film, a semiconductor film such as polycrystalline silicon (Si) doped with impurities, or a metal film such as tungsten (W) is used. The interlayer dielectric film is provided so as to cover the dielectric film and the conductive film.

Note that the semiconductor device described in Patent Document 1 (Japanese Unexamined Patent Application Publication No. 2009-123734) is known as a semiconductor device in which an air gap is provided within the interlayer dielectric film. In the semiconductor device described in Patent Document 1, air gaps are arranged along the direction parallel to the seal ring in order to prevent cracks from reaching the seal ring in dicing or packaging.

### SUMMARY

When a semiconductor device is packaged, stress associated with the shrinkage of sealing resin and stress due to temperature changes in packaging may sometimes be applied to the semiconductor device. In the resistance element included in the semiconductor element, the resistance value changes due to such stresses. For example, when the resistance element included in the semiconductor device is used for the on-chip oscillator, the variation in the resistance value due to the stress applied in packaging can lead to variation of the oscillation frequency of the on-chip oscillator.

Other objects and novel features will become apparent from the following description and the accompanying drawings.

A semiconductor device according to an embodiment includes a semiconductor substrate, a wiring layer, a dielectric film, a conductive film, and an interlayer dielectric film. The semiconductor substrate has a first surface. The wiring layer is placed over the first surface. The wiring layer has a first part and a second part that is located apart from the first part. The conductive film is placed over the first part. The conductive film is placed over the dielectric film. The interlayer dielectric film covers the dielectric film and the conductive film, and is located between the first part and the second part. An air gap is provided within the interlayer dielectric film that is located between the first part and the second part. The air gap extends in a direction crossing the first surface.

According to the semiconductor device according to an embodiment, it is possible to reduce the variation of the resistance value of the conductive film.

### BRIEF DESCRIPTION OF THE DRAWINGS

FIG. 1 is a schematic plan view of a semiconductor device according to a first embodiment;

FIG. 2 is a cross-sectional view of an on-chip oscillator OCO of the semiconductor device according to the first embodiment;

FIG. 3 is an enlarged cross-sectional view taken along line III-III in the area shown in FIG. 2;

FIG. 4 is a top view of the semiconductor device according to the first embodiment;

FIG. 5 is a process chart showing a manufacturing method of the semiconductor device according to the first embodiment;

FIG. 6 is a cross-sectional view after the front end step S1 is performed in the semiconductor device according to the first embodiment;

FIG. 7 is a cross-sectional view after the first interlayer film formation step S21 is performed in the semiconductor device according to the first embodiment;

FIG. 8 is a cross-sectional view after the contact plug formation step S22 is performed in the semiconductor device according to the first embodiment;

FIG. 9 is a cross-sectional view after the wiring layer formation step S23 is performed in the semiconductor device according to the first embodiment;

FIG. 10 is a cross-sectional view after the second interlayer dielectric film formation step S24 is performed in the semiconductor device according to the first embodiment;

FIG. 11 is a cross-sectional view after the via plug formation step S25 is performed in the semiconductor device according to the first embodiment;

FIG. 12 is a cross-sectional view after the dielectric film formation step S26 is performed in the semiconductor device according to the first embodiment;

FIG. 13 is a cross-sectional view after the conductive film formation step S27 is performed in the semiconductor device according to the first embodiment;

FIG. 14 is a cross-sectional view after the second interlayer

dielectric film formation step S24 that is performed just after the conductive film formation step S27 according to the first embodiment;

FIG. 15 is a schematic diagram showing the effect of the semiconductor device according to the first embodiment;

FIG. 16 is an enlarged cross-sectional view of an on-chip oscillator OCO of a semiconductor device according to a second embodiment;

FIG. 17 is a cross-sectional view taken along line XVII-XVII of FIG. 16; and

FIG. 18 is a schematic diagram showing the effect of the semiconductor device according to the second embodiment.

### DETAILED DESCRIPTION

Hereinafter, preferred embodiments will be described with reference to the accompanying drawings. Note that in the following drawings, like or corresponding parts are indicated by like reference numerals and the description thereof will not be repeated.

### First Embodiment

Hereinafter, the configuration of a semiconductor device according to a first embodiment will be described.

As shown in FIG. 1, the semiconductor device according to the first embodiment includes, for example, a memory unit MEM, a logic unit LOG, a power supply unit POW, and an on-chip oscillator unit OCO. The memory unit MEM is configured with, for example, a static random access memory (SRAM) circuit, a dynamic random access memory (DRAM) circuit, a flash memory, or the like. The logic unit LOG is configured with, for example, a complementary metal oxide semiconductor (CMOS) logic circuit, or the like.

The power supply unit POW is configured with, for example, a regulator circuit, or the like. The on-chip oscillator unit OCO is configured with an oscillator circuit including a resistance element R. The on-chip oscillator unit OCO generates a clock signal. The clock signal is supplied to the memory unit MEM, the logic unit LOG, and the like. The memory unit MEM, the logic unit LOG, and the like are operated in synchronization with the clock signal.

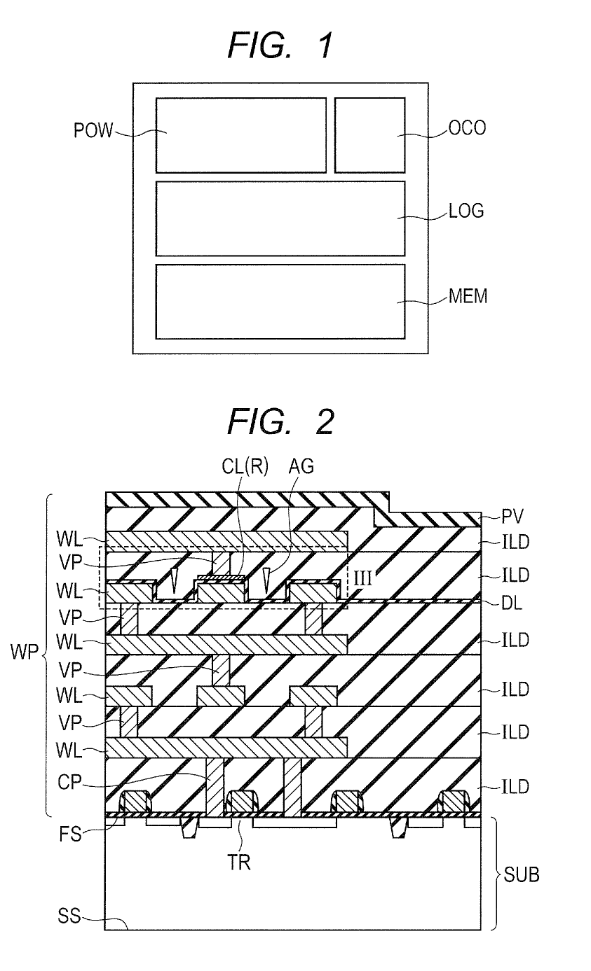

As shown in FIG. 2, the semiconductor device according to the first embodiment includes a semiconductor substrate SUB and a wiring part. WP in the on-chip oscillator unit OCO. The semiconductor substrate SUB has a first surface FS and a second surface SS. The second surface SS is the surface on the opposite side to the first surface FS. The first surface FS is the surface on the side where a transistor TR is formed.

The transistor TR is configured with a source region and a drain region that are arranged to contact the first surface FS of the semiconductor substrate SUB, a gate insulating film placed over the first surface FS of the semiconductor substrate SUB sandwiched between the source region and the drain region, and a gate electrode placed over the gate insulating film.

The wiring part WP is placed over the first surface FS of the semiconductor substrate SUB. The wiring part WP includes a wiring layer WL, a contact plug CP, a via plug VP, an interlayer dielectric film ILD, a dielectric film DL, a conductive film CL, and a passivation film PV.

The number of wiring layers WL may be plural. The material used for the wiring layer WL is, for example, aluminum (Al), Al alloy, or the like. The interlayer dielectric film ILD is provided between each of the wiring layers WL, between the wiring layer WL, which is located on the side closest to the first surface FS of the semiconductor substrate SUB, and the semiconductor substrate SUB and the first surface FS of the semiconductor substrate SUB, and then over the wiring layer WL on the side farthest from the first surface FS of the semiconductor substrate SUB. For example, silicon dioxide (SiO₂) is used for the interlayer dielectric film ILD. The interlayer dielectric film ILD may also be configured with a plurality of layers of different membranes.

The wiring layer WL on the side closest to the first surface FS of the semiconductor substrate SUB, and the source region, drain region, and gate electrode of the transistor TR are electrically coupled to each other through the contact plug CP. For example, W is used for the contact plug CP. Each of the wiring layers WL is electrically coupled by the via plug VP located within the interlayer dielectric film ILD. For example, W is used for the via plug VP.

The passivation film PV is placed over the interlayer dielectric film ILD on the side farthest from the first surface FS of the semiconductor substrate SUB. The passivation film PV may also be configured with a plurality of layers. For example, silicon nitride (SiN), silicon oxynitride (SiON), or other suitable material is used for the passivation film PV.

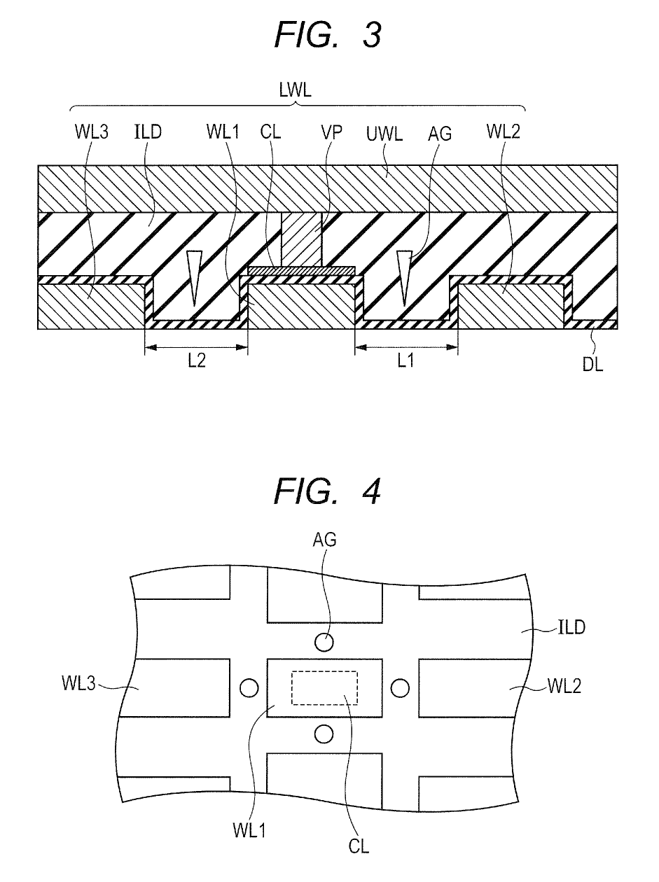

As shown in FIG. 3, the dielectric film DL and the conductive film CL are provided between the wiring layers WL. In the following description, a wiring layer WL, which is located on the side closer to the first surface FS of the semiconductor substrate SUB than the dielectric film DL and the conductive film CL, are referred to as a lower layer wiring layer LWL. Further, a wiring layer WL, which is located on the side farther from the first surface FS of the semiconductor substrate SUB than the dielectric film DL and the conductive film CL, is referred to as an upper wiring layer UWL. The lower layer wiring layer LWL can include all lower layer wiring layers LWL except the one that is located on the side farthest from the first surface FS of the semiconductor substrate SUB.

The lower layer wiring layer LWL has a first part WL1, a second part WL2, and a third part WL3. The first part WL1 is provided apart from the second part LW2 and the third part WL3. The first part LW1 is provided between the second part WL2 and the third part WL3.

The first part WL1 and the second part WL2 are distant from each other by a distance L1. The first part WL1 and the third part WL3 are distant from each other by a distance L2. The distance L1 and the distance L2 are smaller than the wiring interval in the area in which the conductive film CL is not formed. The second part WL2 and the third part WL3 may be dummy patterns. The dummy pattern is the part of the wiring layer WL that does not transmit electrical signals.

The dielectric film DL is placed over the lower layer wiring layer LWL. More specifically, the dielectric film DL is placed over the first part WL2, the second part WL2, and the third part WL3. For example, SiO₂ is used for the dielectric film DL. The conductive film CL is placed over the dielectric film DL. The conductive film CL is electrically coupled to the upper layer wiring layer UWL through the via plug VP. The conductive film CL configures the resistance element R of the on-chip oscillator.

The conductive film CL is formed by a conductive material. The conductive material may be a metallic material. The metallic material includes not only pure substances and alloys of metallic elements but also conductive compounds containing metallic elements as constituent components. As the metallic material configuring the conductive film CL, for example, W, TiN, or other metals are used. The conductive material may also be a non-metallic material. For example, polycrystalline Si doped with impurities is used as the non-metallic material of the conductive film CL.

The interlayer dielectric film ILD located between the lower layer wiring layer LWL and the upper layer wiring layer UWL covers the dielectric film DL and the conductive film CL. The interlayer dielectric film ILD fills the space between the first part WL1 and the second part WL2 as well as the space between the first part WL1 and the third part WL3.

An air gap AG is provided within the interlayer dielectric film ILD. The air gap AG is a sealed space that is formed within the interlayer dielectric film. The air gap AG is provided within the interlayer dielectric film ILD located between the first part WL1 and the second part WL2. It may also be possible that the air gap AG is provided between the interlayer insulating films ILD located between the first part WL1 and the second part WL2.

The air gap AG extends in a direction crossing the first surface FS of the semiconductor substrate SUB. Preferably, the air gap AG extends in a direction orthogonal to the first surface FS of the semiconductor substrate SUB. Preferably, the air gap AG extends to reach a position facing the conductive film CL. More preferably, the air gap AG extends beyond the position facing the conductive film CL. Here, facing the conductive film CL means that the position is equal to the conductive film CL in the height direction (the direction orthogonal to the first surface FS of the semiconductor substrate SUB).

As shown in FIG. 4, (in FIG. 4, the structure on the upper layer side than the lower layer wiring layer LWL is omitted in order to clarify the plan shape of the lower layer wiring layer LWL, and the position of the conductive film CL is shown by the dashed line), the air gap AG may also be provided on the four sides of the conductive film CL in a plan view (as seen from the direction orthogonal to the first surface FS of the semiconductor substrate SUB). From the other point of view, the air gap AG may also be provided to surround the conductive film CL in a plan view.

Hereinafter, the manufacturing method of the semiconductor device according to the first embodiment will be described.

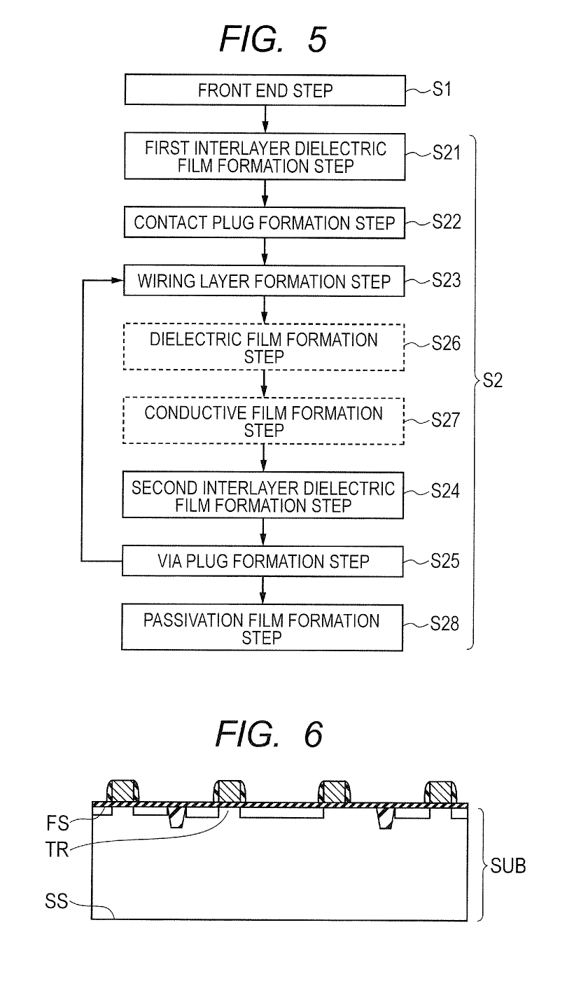

As shown in FIG. 5, the manufacturing method of the semiconductor device according to the first embodiment includes a front end step S1 and a back end step S2.

The back end step S2 includes a first interlayer dielectric film formation step S21, a contact plug formation step S22, a wiring layer formation step S23, a second interlayer dielectric film formation step S24, s via plug formation step S25, a dielectric film formation step S26, a conductive film formation step S27, and a passivation film formation step S28.

As shown in FIG. 6, in the front end step S1, the transistor TR is formed on the side of the first surface FS of the semiconductor substrate SUB. The front end step S1 is performed by a conventionally known method.

In other words, the formation of the source region and the drain region hat configure the transistor TR are performed by, for example, ion implantation. Further, the formation of the gate insulating film configuring the transistor TR is performed by, for example, thermal oxidization of the first surface FS of the semiconductor substrate SUB. The formation of the gate electrode configuring the transistor TR is performed by, for example, depositing polycrystalline Si doped with impurities over the gate insulating film, while patterning the deposited polycrystalline Si by photolithography.

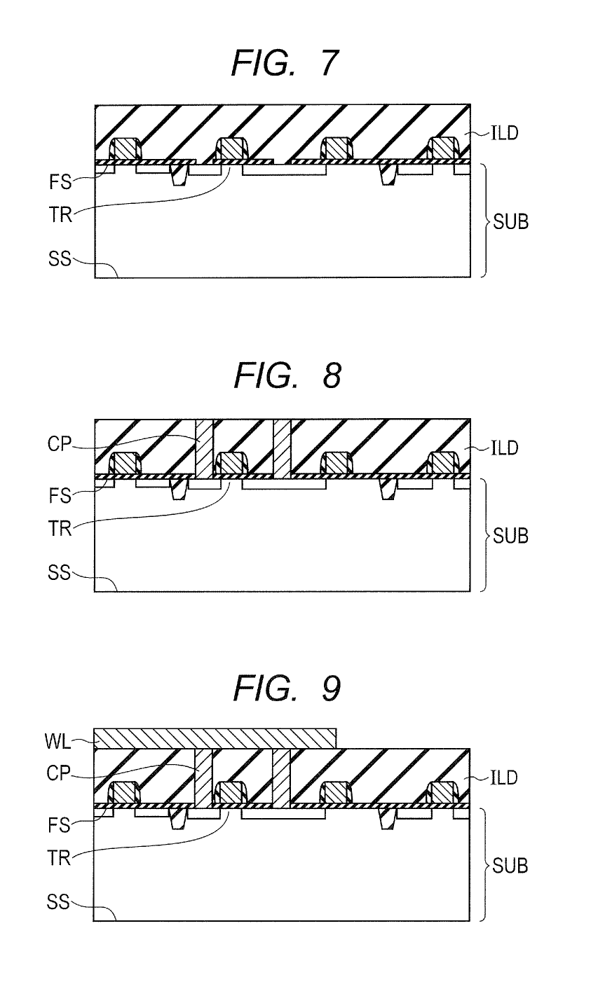

As shown in FIG. 7, in the first interlayer dielectric film formation step S21, the interlayer dielectric film ILD is formed overt the first surface FS of the semiconductor substrate SUB. The formation of the interlayer dielectric film ILD is performed by depositing the material of the interlayer dielectric film ILD over the first surface FS of the semiconductor surface SUB by chemical vapor deposition (CVD), while planarizing the deposited material of the interlayer dielectric film ILD by chemical mechanical polishing (CMP) or other planarization methods.

As shown in FIG. 8, in the contact plug formation step S22, the contact plug CP is formed within the interlayer dielectric film ILD located on the side closest to the first surface SF of the semiconductor substrate SUB.

In the formation of the contact plug CP, first a contact hole is opened in the interlayer dielectric film ILD that is located over the source region, the drain region, and the gate electrode. The opening of the contact hole is performed by, for example, anisotropic etching such as reactive ion etching (RIE).

In the formation of the contract plug CP, second the contact hole is filled with the material of the contact plug CP. The material of the contact plug CP is deposed by CVD or other appropriate method.

In the wiring layer formation step S23, as shown in FIG. 9, the wiring layer WL is formed over the interlayer dielectric film ILD. The formation of the wiring layer WL is performed by depositing the material of the wiring layer WL over the Interlayer dielectric film ILD by sputtering or other appropriate method, while patterning the deposited material of the wiring layer WL by photolithography.

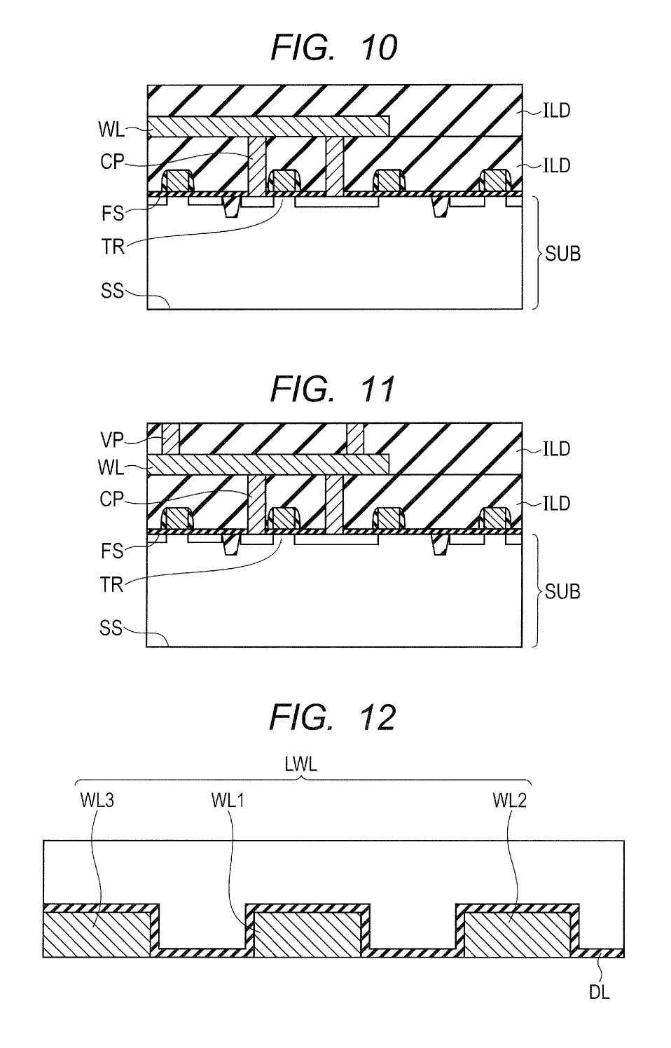

In the second interlayer dielectric film formation step S24, as shown in FIG. 10, the interlayer dielectric film ILD is formed over the wiring layer WL. The formation of the interlayer dielectric film ILD is performed in the same way as in the first interlayer dielectric film formation step S21. In the via plug formation step S25, as shown in FIG. 11, the via plug VP is formed within the interlayer dielectric film ILD. The formation of the via plug VP is performed in the same way as the formation of the contact plug CP in the contact plug formation step S22.

A plurality of wiring layers WL, interlayer dielectric films ILD provided between each of the wiring layers WL, and via plugs VP electrically coupling the respective wiring layers WL are formed by repeating the wiring layer formation step S23, the second interlayer dielectric film formation step S24, and the via plug formation step S25. Note that the dielectric film formation step S26 and the conductive film formation step S27, which are described below, are performed at least one time.

In the passivation film formation step S28, the passivation film PV is formed over the interlayer dielectric film ILD located on the side farthest from the first surface FS of the semiconductor substrate SUB. In this way, the structure of the semiconductor device according to the first embodiment shown in FIG. 2 is formed. The formation of the passivation film PV is performed by depositing the material of the passivation film PV by CVD or other appropriate method.

Hereinafter, the dielectric film formation step S26 and the conductive film formation step S27 will be descried in detail.

As shown in FIG. 12, in the dielectric film formation step S26, the dielectric film DL is formed over the wiring layer WL. The formation of the dielectric film DL is performed by depositing the material of the dielectric film DL over the wiring layer WL by CVD or other appropriate method.

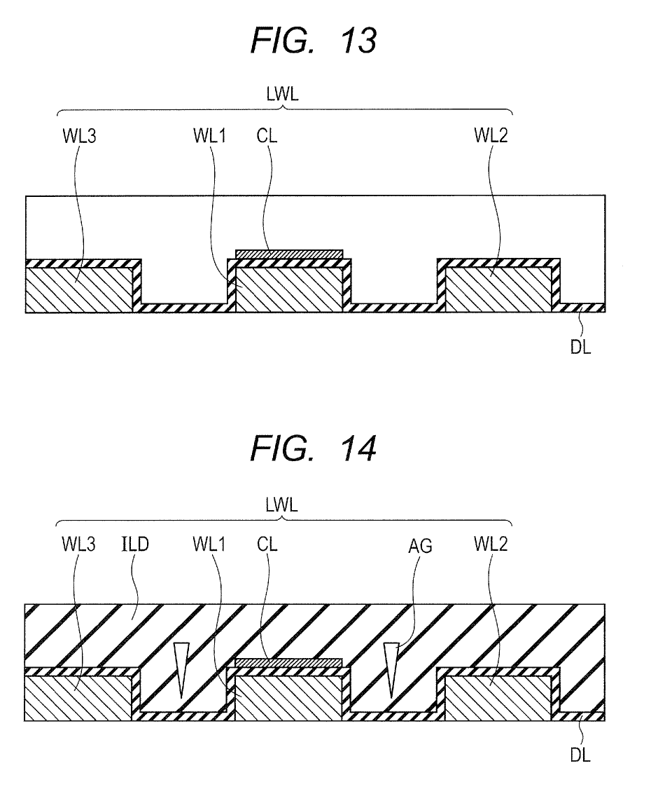

As shown in FIG. 13, in the conductive film formation step S27, the conductive film CL is formed over the dielectric film DL. The formation of the conductive film CL is performed by depositing the material of the conductive film CL by sputtering or other appropriate method, while patterning the deposited material of the conductive film CL by photolithography.

After the conductive film formation step S27, the second interlayer dielectric film formation step S24 is performed. As described above, the distance L1 which is the distance between the first part WL1 and the second part WL2, as well as the distance L2 which is the distance between the first part WL1 and the third part WL3 are both smaller than the wiring interval in the area in which the conductive film CL is not formed.

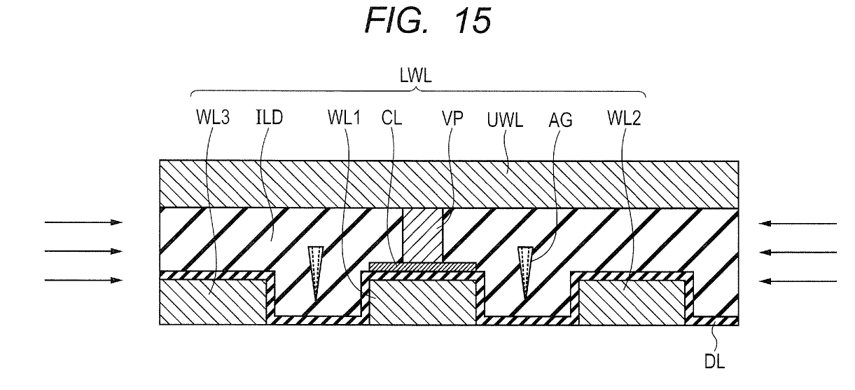

Thus, as shown in FIG. 14, in the second interlayer dielectric film formation step S24 that is performed just after the conductive film formation step S27, the space between the first part WL1 and the second part WL2 as well as the space between the first part WL1 and the third part WL3 are not completely filled with the material of the interlayer dielectric film ILD. Consequently, in the second interlayer dielectric film formation step S24 performed after the conductive film formation step S27, the air gap AG is formed within the interlayer dielectric film ILD located between the first part WL1 and the second part WL2 and within the interlayer dielectric film ILD located between the first part WL1 and the third part WL3. In other words, the second interlayer dielectric film formation step S24 performed after the conductive film formation step S27 includes an air gap formation step S24a to generate the air gap AG.

Hereinafter, the effect of the semiconductor device according to the first embodiment will be described.

The semiconductor device according to the first embodiment is packaged by molding it with sealing resin. It is assumed that the temperature change in packaging is Δt and the thermal expansion coefficient of the conductive film CL is α. The conductive film CL tends to extend by α×ΔT due to temperature change in packaging.

When the air gap AG is not provided in the semiconductor device according to the first embodiment, the deformation of the conductive film CL is constrained by the interlayer dielectric film ILD covering the conductive film CL. For this reason, a stress of −α×E×ΔT (where E is the Young's modulus of the conductive film CL) is applied to the conductive film CL due to temperature change in packaging.

The sealing resin shrinks upon curing. When the air gap AG is not provided, the stress associated with the shrinkage of the sealing resin upon curing is transmitted to the conductive film CL through the interlayer dielectric film ILD. For this reason, when the air gap AG is not provided in the semiconductor device according to the first embodiment, there is a risk that the resistance value of the conductive film CL may be changed after packaging.

In the semiconductor device according to the first embodiment, when the air gap AG is provided, even if a stress (indicated by the arrow in FIG. 15) generated in packaging is applied, the air gap AG is deformed by the stress as shown in FIG. 15 (the shape of the air gap AG after deformation is indicated by the dashed line in FIG. 15), so that the stress is not likely to be transmitted to the conductive film CL. As a result, in the semiconductor device according to the first embodiment, the resistance value of the conductive film CL is not likely to be changed after packaging.

As described above, in the semiconductor device according to the first embodiment, it is possible to reduce the variation of resistance value that occurs in the conductive film CL after packaging.

When the resistance element R of the on-chip oscillator, which is included in the semiconductor device according to the first embodiment, is configured with the conductive film CL, the variation of the resistance value that occurs in the conductive film CL after packaging is reduced. As a result, it is possible to reduce the variation of the oscillation frequency of the on-chip oscillator included in the semiconductor device according to the first embodiment, after packaging.

When the air gap AG extends to reach a position facing the conductive film CL (or when the air gap AG extends beyond the position facing the conductive film CL), the deformation of the conductive film CL associated with the temperature change in packaging is not more likely to be constrained by the environment. Thus, in this case, it is possible to further reduce the variation of the resistance value of the conductive film CL after packaging.

The resistance value change in the metallic material associated with the temperature change is small as compared to that in the non-metallic material. For this reason, when the conductive film CL is configured with a metallic material in the semiconductor device according to the first embodiment, it is possible to reduce the variation of the resistance value of the conductive film CL associated with the change in the use environment temperature of the semiconductor device.

Titanium nitride is a material in which the variation of the resistance value associated with the temperature change is particularly small. For this reason, when the conductive film CL is configured with titanium nitride in the semiconductor device according to the first embodiment, it is possible to reduce the variation of the resistance value of the conductive film CL associated with the change in the use environment temperature of the semiconductor device.

During packaging, stress can be applied to the conductive film CL in different directions. In the semiconductor device according to the first embodiment, when the air gap AG is provided on the four sides of the conductive film CL (or the air gap AG is provided to surround the conductive film CL) in a plan view, it is possible to alleviate the stress that occurs during packaging, in different directions. Thus, in this case, it is possible to further reduce the variation of the resistance value of the conductive film CL after packaging.

In the semiconductor device according to the first embodiment, when the second part WL2 and the third part WL3 are dummy patterns, it is possible to form the air gap AG in a desired position, regardless of the layout of the wiring layer WL for transmitting electrical signals. In other words, in this case, it is possible to reduce the variation of the resistance value of the conductive film CL after packaging, while maintaining the flexibility of the layout of the wiring layer WL. Further, in this case, the air gap AG can be formed only in the area in which alleviation of stress is required, so that the increase in the leak current associated with the formation of the air gap AG can be minimized.

### Second Embodiment

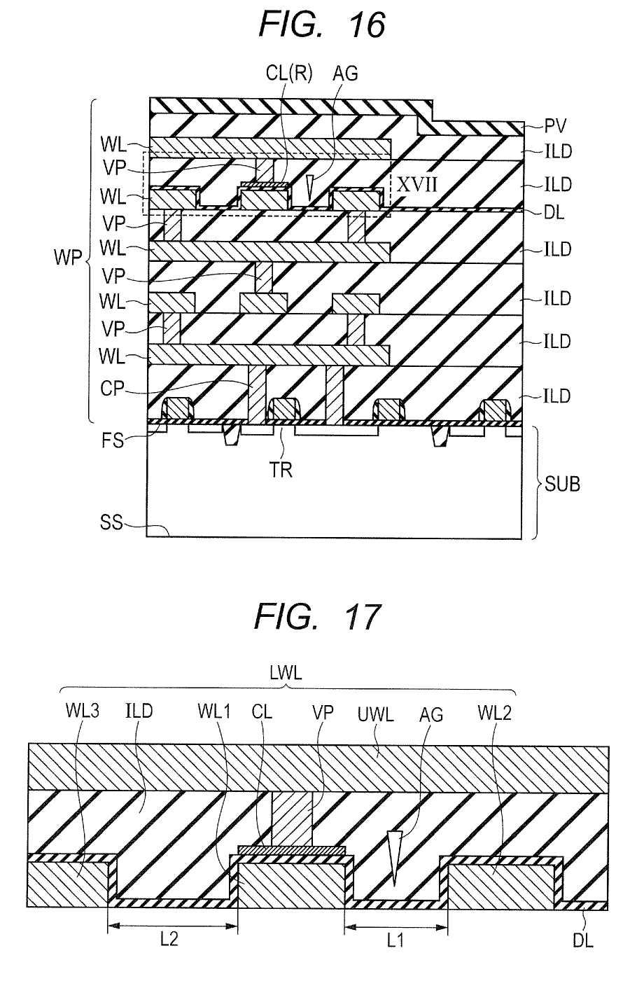

As shewn in FIGS. 16 and 17, a semiconductor device according to a second embodiment includes: a lower layer wiring layer LWL including a first part WL1, a second part WL2, and a third part WL3; a dielectric film DL placed over the first part WL1; a conductive film CL placed over the dielectric film DL; and an interlayer dielectric film. ILD that covers the dielectric film DL and the conductive film CL. In this regard, the semiconductor device according to the second embodiment is similar to the semiconductor according to the first embodiment.

On the other hand, in the semiconductor device according to the second embodiment, the air gap AG is provided within the interlayer dielectric, film ILD located between the first part WL1 and the second part WL2, but not within the interlayer dielectric film ILD located between the first part WL1 and the third part WL3. In other words, in the semiconductor device according to the second embodiment, the air gap AG is not provided on the four sides of the conductive film CL in a plan view. In this regard, the semiconductor device according to the second embodiment is different from the semiconductor device according to the first embodiment.

In the semiconductor device according to the second embodiment, the distance L1 which is the distance between the first part WL1 and the second part WL2 is smaller than the distance L2 which is the distance between the first part WL1 and the third part WL3. In the case in which the distance L1 is smaller than the distance L2, this includes the case in which the third part W13 is not provided. The distance L1 is smaller than the wiring interval in the area in which the conductive film CL is not formed. On the other hand, the distance L2 is equal to or more than the wiring interval in the area in which the conductive film CL is not formed.

For this reason, the interlayer dielectric film ILD can completely fill the space between the first part WL1 and the second part WL2 but may not completely fill the space between the first part WL1 and the second part WL2. Consequently, the air gap AG is provided within the interlayer dielectric film ILD located between the first part WL1 and the second part WL2, but not provided within the interlayer dielectric film ILD located between the first part WL1 and the third part WL3.

The position in which the air gap AG is provided as well as the position in which the air gap AG is not provided may be determined according to the position in the semiconductor device according to the second embodiment over which the conductive film CL is placed in a plan view. For example, when the conductive film C1 is located in the vicinity of the upper right corner of the semiconductor device according to the second embodiment in a plan view, the air gap AG may also be located only above and right of the conductive film CL in a plan view as shown in FIG. 8.

The manufacturing method of the semiconductor device according to the second embodiment is similar to the manufacturing method of the semiconductor device according to the first embodiment. However, in the manufacturing method of the semiconductor device according to the second embodiment, the wiring layer WL is formed in such a way that the distance L1 is smaller than the distance L2 in the wiring layer formation step S23 that is performed just before the dielectric film formation step S26.

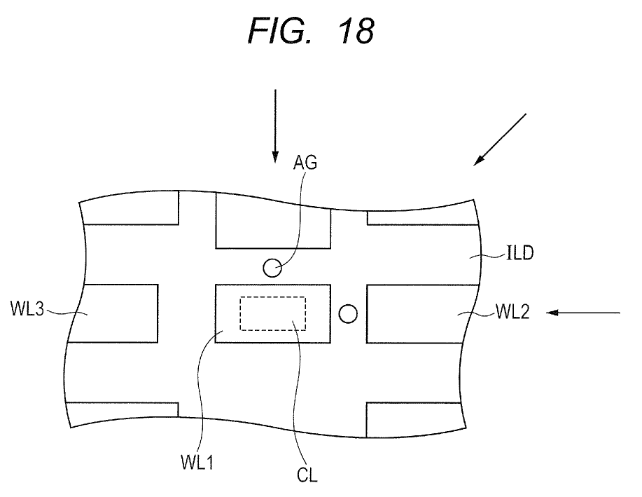

During packaging, the stress differs depending on the position in the semiconductor device according to the second embodiment in a plan view. For example, in the vicinity of the upper right corner of the semiconductor device according to the second embodiment in a plane view, as shown in FIG. 18 (the directions of the stress are shown by the arrows in FIG. 18), the stress from the left and downward is not likely to affect the semiconductor device according to the second embodiment. Thus, in this example, the variation of the resistance value of the conductive film CL is not likely to occur due to the stress associated with the temperature change in packaging, even if the air gap AG is not provided on the left and lower side of the conductive film CL in a plan view.

As described above, in the semiconductor device according to the second embodiment, the air gap AG is provided only in the direction in which alleviation of the stress associated with the temperature change in packaging is required, and not provided in other directions in order to achieve space saving in the semiconductor device according to the second embodiment. Further, in the semiconductor device according to the second embodiment, the air gap is not provided in a position in which alleviation of the stress is less required, in order to achieve stress alleviation while minimizing the leak current between wirings.

While the invention made by the present inventors has been concretely described based on the embodiments, the present invention is not limited to the exemplary embodiments. It is apparent to those skilled in the art that various modifications and variations can be made without departing from the scope of the present invention.

What is claimed is:

1. A semiconductor device comprising:
a semiconductor substrate having a first surface;
a wiring layer that has a first part as well as a second part provided apart from the first part and is placed over the first surface;
a dielectric film placed over the first part;
a conductive film that is placed over the dielectric film and configured with a conductive material; and
an interlayer dielectric film covering the dielectric film and the conductive film, which is located between the first part and the second part,
wherein an air gap extending in a direction crossing the first surface is provided between the first part and the second part.

2. The semiconductor device according to claim 1,
wherein the air gap extends to reach a position facing the conductive film.

3. The semiconductor device according to claim 1,
wherein the second part is a dummy pattern.

4. The semiconductor device according to claim 1,
wherein the wiring layer further comprises a third part provided apart from the first part,
wherein the interlayer dielectric film is located between the first part and the third part,
wherein the air gap is not provided between the first part and the third part, and
wherein the distance between the first part and the second part is smaller than the distance between the first part and the third part.

5. The semiconductor device according to claim 1,
wherein the conductive material is a metallic material.

6. The semiconductor device according to claim 5,
wherein the metallic material is titanium nitride.

7. The semiconductor device according to claim 1, further comprising an on-chip oscillator having a resistance element,
wherein the resistance element is configured with the conductive film.

8. A method of manufacturing a semiconductor device, comprising the steps of:
forming a wiring layer having a first part and a second part provided apart from the first part, over a first surface of a semiconductor substrate; forming a dielectric film over the first part;
forming a conductive film configured with a conductive material, over the dielectric film; and
forming an interlayer dielectric film that covers the dielectric film and the conductive film, and is located between the first part and the second part,
wherein the step of forming the interlayer dielectric film comprises a step of forming an air gap extending in a direction crossing the first surface, within the interlayer dielectric film located between the first part and the second part.

9. The method of manufacturing a semiconductor device according to claim 8,
wherein the conductive film material is a metallic material.

10. The method of manufacturing a semiconductor device according to claim 9,
wherein the metallic material is titanium nitride.
